(19) United States
(12) Patent Application Publication
(10) Pub. No.: US 2025/0294959 A1
(43) Pub. Date: Sep. 18, 2025

(54) LIGHT-EMITTING ELEMENT AND DISPLAY DEVICE

(71) Applicant: Sharp Display Technology Corporation, Kameyama City, Mie (JP)

(72) Inventors: Yang QU, Kameyama City, Mie (JP); Xiaohuan FU, Kameyama City, Mie (JP)

(21) Appl. No.: 18/862,272

(22) PCT Filed: Jun. 27, 2022
(86) PCT No.: PCT/JP2022/025554

§ 371 Date: Nov. 1, 2024

(51) Int. Cl. H10K 50/165; H10K 50/15; H10K 102/00

(52) U.S. Cl. CPC H10K 50/165; H10K 50/15; H10K 2102/331

(57) ABSTRACT

A light-emitting element is provided with an electron transport layer that can achieve carrier balance without impairing the high hole injection capability of nickel oxide nanoparticles. The light-emitting element includes a first electrode, a functional layer, and a second electrode. The functional layer includes a hole injection layer, an emission layer, and an electron transport layer. The hole injection layer contains a zinc oxide nanoparticle. The electron transport layer contains a composite zinc oxide nanoparticle. The composite zinc oxide nanoparticle includes a zinc oxide carrier particle supporting a zinc oxide nanoparticle doped with a metal atom as a dopant.

### TECHNICAL FIELD

The present disclosure relates to a light-emitting element and a display device.

### BACKGROUND ART

In recent years, various display devices provided with light-emitting elements have been developed; in particular, a display device provided with quantum-dot light-emitting diodes (QLEDs) or organic light-emitting diodes (OLEDs) has attracted much attention because it can achieve low power consumption, thickness reduction, high image quality, and other advantages.

For example, Patent Literature 1 describes a display screen using a hybrid light-emitting diode provided with a backplane, and an anode positioned on a surface of the backplane, wherein a red quantum-dot light-emitting diode (red QLED), a green quantum-dot light-emitting diode (green QLED), and a blue organic light-emitting diode (blue OLED) are respectively disposed in a first region, a second region, and a third region on the anode surface, wherein the second and third regions do not overlap each other, and wherein a cathode is disposed on the surfaces of the red QLED, green QLED, and blue OLED.

To improve the reliability of a quantum-dot light-emitting diode (QLED), Patent Literature 1 describes using NiO-NPs (nickel oxide nanoparticles) as a hole injection layer (HIL), and using ZnO as an electron transport layer (ETL).

### CITATION LIST

### Patent Literature

Patent Literature 1: International Publication No. WO2020-041993

### SUMMARY

### Technical Field

Nickel oxide nanoparticles, which are used in the light-emitting element described in Patent Literature 1, have a high hole injection capability as a material of a hole injection layer (HTL or hole transport layer), whereas ZnO has a low electron transport capability as a material of an electron transport layer (ETL). Hence, it is difficult to achieve carrier balance between the hole transport layer and electron transport layer, thus lowering external quantum efficiency (EQE).

The present disclosure has been made in view of the above-described problem. It is an object of the present disclosure to provide a light-emitting element and a display device that are provided with such a novel electron transport layer as to be able to achieve carrier balance by using nickel oxide nanoparticles for a hole transport layer without impairing their high hole injection capability.

### Solution to Problem

To solve the above problem, a light-emitting element according to one aspect of the present disclosure includes the following: a first electrode; a second electrode; and a functional layer provided between the first electrode and the second electrode. The functional layer includes a hole transport layer, an emission layer, and an electron transport layer. The hole transport layer contains a nickel oxide nanoparticle. The electron transport layer contains a composite zinc oxide nanoparticle. The composite zinc oxide nanoparticle includes a zinc oxide carrier particle supporting a zinc oxide nanoparticle doped with a metal atom as a dopant.

Further, to solve the above problem, a display device according to one aspect of the present disclosure is provided with the following: a substrate; and a plurality of light-emitting elements on the substrate. Each of the plurality of light-emitting elements includes a first electrode, a second electrode, and a functional layer provided between the first electrode and the second electrode. The functional layer includes a hole transport layer, an emission layer, and an electron transport layer. The hole transport layer contains a nickel oxide nanoparticle. The electron transport layer contains a composite zinc oxide nanoparticle. The composite zinc oxide nanoparticle includes a zinc oxide carrier particle supporting a zinc oxide nanoparticle doped with a metal atom as a dopant.

### Advantageous Effect of Disclosure

The aspects of the present disclosure can provide a light-emitting element and a display device both provided with such a novel electron transport layer as to be able to achieve carrier balance by using nickel oxide nanoparticles for a hole transport layer without impairing their high hole injection capability.

### BRIEF DESCRIPTION OF DRAWINGS

FIG. 1 is a cross-sectional view of the schematic configuration of a light-emitting element 1 according to one embodiment of the present disclosure.

FIG. 2 illustrates the schematic of MgZnO@ZnO-NPs contained in an electron transport layer 11ET provided in the light-emitting element 1 according to the embodiment of the present disclosure.

FIG. 3(a) is a cross-sectional view of the schematic configuration of a red light-emitting element 1R in one embodiment of the present disclosure; FIG. 3(b) is a cross-sectional view of the schematic configuration of a green light-emitting element 1G provided in a display device in one embodiment of the present disclosure; and FIG. 3(c) is a cross-sectional view of the schematic configuration of a blue light-emitting element 1B provided in the display device in the embodiment of the present disclosure.

FIG. 4 is a plan view of the schematic configuration of a display region of the display device, 100, according to the embodiment of the present disclosure.

FIG. 5 is a cross-sectional view of the schematic configuration of the display region of the display device 100 according to the embodiment of the present disclosure.

FIG. 6 schematically illustrates a scheme of a method for producing composite zinc oxide nanoparticles (MgZnO@ZnO-NPs) contained in a hole transport layer of the light-emitting element according to the embodiment of the present disclosure.

### DESCRIPTION OF EMBODIMENTS

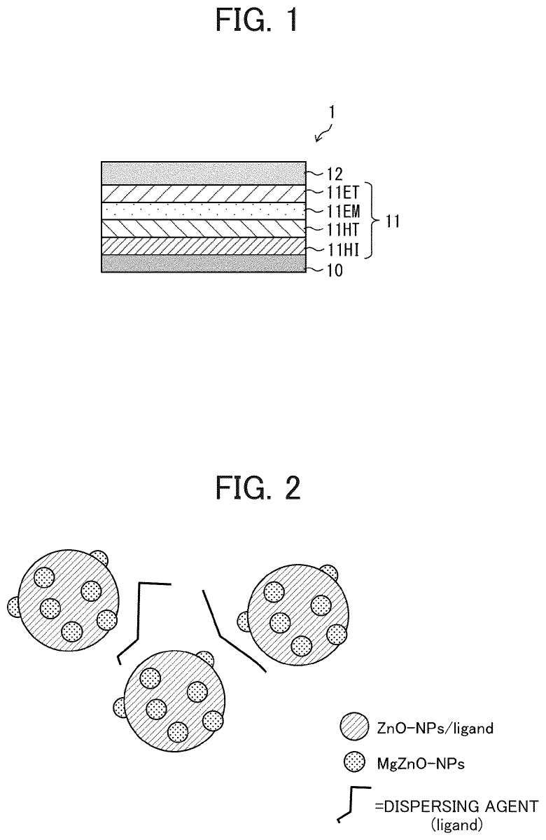

One embodiment of the present disclosure will be described below with reference to FIG. 1.

It is noted that unless otherwise specified in the Description, “A to B” denoting a numerical range means “not less than A and not more than B”.

It is also noted that “nanoparticles” will be abbreviated as “NPs” in some cases in the Description.

The light-emitting element 1 in this embodiment is applied to quantum-dot light-emitting elements including quantum-dot light-emitting diodes (QLEDs). By extension, the light-emitting element 1 is applied to light-emitting devices (display devices) provided with the quantum-dot light-emitting element in this embodiment and an array substrate.

### Light-Emitting Element 1

First, the configuration of a light-emitting element 1 including a quantum-dot light-emitting diode (QLED), in the embodiment of the present disclosure will be described with reference to FIG. 1. FIG. 1 is a cross-sectional view of the schematic configuration of the light-emitting element 1 in this embodiment.

The light-emitting element 1 in this embodiment is provided with the following on a first electrode 10 that is an anode, in the stated order as illustrated in FIG. 1: a hole injection layer (HIL) 11HI, a hole transport layer (HTL) 11HT, an emission layer (EML) 11EM, an electron transport layer (ETL) 11ET, and a second electrode 12 that is a cathode. A functional layer 11 is provided with the hole injection layer 11HI, hole transport layer 11HT, emission layer 11EM, and electron transport layer 11ET and is provided between the first electrode 10 and second electrode 12.

The light-emitting element 1 illustrated in FIG. 1 may be either a top-emission type or a bottom-emission type. The light-emitting element 1 needs to be structured such that the second electrode 12 or cathode is disposed above the first electrode 10 or anode, such that the first electrode 10 or anode is made of an electrode material that reflects visible light, and such that the second electrode 12 or cathode is made of an electrode material that transmits visible light. For a bottom-emission, the light-emitting element 1 needs to be structured such that the second electrode 12 or cathode is disposed above the first electrode 10 or anode, such that the first electrode 10 or an anode is made of an electrode material that transmits visible light, and such that the second electrode 12 or cathode is made of an electrode material that reflects visible light.

The electrode material that reflects visible light may be any material that can reflect visible light and is conductive; examples include metal materials, such as Al, Cu, Au, Mg, Li, and Ag, alloys of these metal materials, a stack of the metal material and a transparent metal oxide (e.g., an indium tin oxide, an indium zinc oxide, and an indium gallium zinc oxide), and a stack of the alloy and transparent metal oxide.

On the other hand, the electrode material that transmits visible light may be any material that can transmit visible light and is conductive; examples include a transparent metal oxide (e.g., an indium tin oxide, an indium zinc oxide, and an indium gallium zinc oxide), a thin film made of metal, such as Al or Ag, and a nanowire made of metal, such as Al or Ag.

The first electrode 10 and the second electrode 12 can be formed through a typical method of electrode formation; examples include physical vapor deposition (PVD), such as vacuum evaporation, sputtering, EB evaporation, and ion plating, and chemical vacuum evaporation (CVD). Further, the first electrode 10 and the second electrode 12 may undergo such patterning as to be formed into a desired pattern accurately; specific examples include photolithography and ink-jet printing.

The light-emitting element 1 may have a forward stacked structure in one embodiment by way of example; the light-emitting element 1 may have an inverted stacked structure. The light-emitting element 1 of forward stacked structure is provided with the first electrode 10 or anode, and the second electrode 12 or cathode positioned above the first electrode 10. The functional layer 11 including the emission layer and provided between the first electrode 10 or anode and the second electrode 12 or cathode can be formed by, for instance, stacking a hole injection layer, a hole transport layer, a red emission layer, an electron transport layer, and an electron injection layer sequentially on the first electrode 10. Although not shown, a light-emitting element of inverted stacked structure is provided with a first electrode that is a cathode, and a second electrode that is an anode and is positioned above the first electrode. A functional layer including an emission layer and provided between the first electrode or cathode and the second electrode or anode can be formed by, for instance, stacking an electron injection layer, an electron transport layer, a green emission layer, a hole transport layer, and a hole injection layer sequentially from on first electrode. In one embodiment, the functional layer provided in a light-emitting element of either forward stacked structure or inverted stacked structure needs to contain nickel oxide nanoparticles in the hole transport layer or the hole injection layer. Although this embodiment describes an instance where the hole injection layer contains nickel oxide nanoparticles, the hole injection layer is not an essential constituent.

### Hole Injection Layer

A light-emitting element may be provided with a plurality of hole transport layers in order to enhance hole injection efficiency. The light-emitting element 1 according to one embodiment is provided with the hole injection layer 11HI and the hole transport layer 11HT. The hole injection layer 11HI injects holes from the first electrode 10 or anode into the hole transport layer 11HT. A hole injection layer is a layer that transports holes from a first electrode that is an anode to an emission layer and is hence described as one aspect of a hole transport layer. The hole injection layer 11HI contains an inorganic material as a hole injection material. The inorganic material contains nickel oxide nanoparticles.

The hole injection layer 11HI may be applied collectively to the subpixels of a plurality of light-emitting elements 1 through spin coating using a dispersion solution containing nickel oxide nanoparticles dispersed in a polar solvent, such as water, ethanol, or dimethyl sulfoxide, or may be applied separately to each subpixel through ink-jet printing or other methods. The dispersion solution containing nickel oxide nanoparticles may contain a dispersing material, such as thiol or amine.

The nickel oxide nanoparticles assume a positive charge on their surfaces, and the zeta-potential of the particles themselves can be positive. The nickel oxide nanoparticles may be provided with a ligands, like quantum dots that can be contained in the emission layer 11EM, which will be described later on, and composite nickel oxide particles contained in the electron transport layer 11ET, which will be described later on. Alternatively, the dispersion solution containing nickel oxide nanoparticles may contain ligands as a dispersing material.

The hole injection layer 11HI including nickel oxide nanoparticles may be formed by, for example, electrophoretic deposition. In the electrophoretic deposition, a hole injection layer with nickel oxide nanoparticles deposited thereon can be formed by applying a dispersion solution containing nickel oxide nanoparticles onto a first electrode that is an anode, followed by applying a voltage between a counter electrode, which is not shown, and the first electrode or anode.

The D50, so-called median diameter, of the nickel oxide nanoparticles contained in the hole injection layer 11HI is determined as, for example, a cumulative distribution on a volumetric basis. This D50 needs to fall within 10 to 500 nm and preferably falls within 10 to 30 nm.

The nickel oxide nanoparticles can be NiO-NPs for instance. Other than the foregoing, the hole injection layer 11HI may be formed through sputtering.

### Hole Transport Layer

The hole transport layer 11HT transports holes injected from the hole injection layer 11HI to the emission layer 11EM. The hole injection layer 11HT is a layer formed on the hole injection layer 11HI. The hole transport layer 11HT may be made of any hole-transporting material that can stabilize hole transport to the emission layer 11EM. The hole transport layer 11HT is preferably made of a hole-transporting material with high hole mobility. Furthermore, a preferable hole-transporting material is one that can avoid penetration of electrons moved from the second electrode 12 or cathode (i.e., an electron-blocking material). This is because these hole-transporting materials can enhance the efficiency of hole-and-electron recombination within the emission layer 11EM. The hole transport layer 11HT can be made of a hole-transporting material, such as NiO-NP, poly-TPD, polyvinyl carbazole (PVK), or poly[(9,9-dioctylfluorenyl-2,7-dyl)-co-(4,4′-(N-(4-sec-butylphenyl))diphenylamine)] (TFB). As described above, the hole transport layer 11HT can be a layer that avoids, for instance, electrons to be transported from the electron transport layer 11ET to the emission layer 11EM from escaping the first electrode 10.

The hole transport layer 11HT may be applied collectively to the subpixels of the plurality of light-emitting elements 1 through dip coating or spin coating using a dispersion solution with a hole-transporting material dispersed or may be applied separately to each subpixel through ink-jet printing or other methods.

### Emission Layer

The emission layer 11EM emits light upon recombination of a hole transported from the first electrode 10 or anode and an electron transported from the second electrode electrons 12 or cathode. Although the emission layer 11EM in this embodiment is a quantum-dot emission layer including any one of quantum dots (QDs, semiconductor nanoparticles) of the respective colors as an emission material, the emission layer 11EM may be a layer including organic light-emitting diodes (OLEDs).

Each quantum dot (QD) may have, for example, a core structure, a core-shell structure, a core-shell-shell structure, or a core-shell structure with the shell ratio continuously changed. In a core-structured quantum dot (QD), a ligand is provided on the core's surface. In a shell-structured quantum dot (QD), a ligand is provided on the shell's surface. In a mono-component system, the core portion can be composed of, for example, Si or C. In a binary system, the core portion can be composed of, for example, CdSe, CdS, CdTe, InP, GaP, InN, ZnSe, ZnS, or ZnTe. In a ternary system, the core portion can be composed of, for example, CdSeTe, GaInP, or ZnSeTe. In a quaternary system, the core portion can be composed of, for example, AIGS. In a binary system, the shell portion can be composed of, for example, CdS, CdTe, CdSe, ZnS, ZnSe, or ZnTe. In a ternary system, the shell portion can be composed of, for example, CdSSe, CdTeSe, CdSTe, ZnSSe, ZnSTe, ZnTeSe, or AlP.

It is noted that a quantum dot (QD) is a nanoscale semiconductor crystal having a unique optical property of quantum mechanics. Each quantum dot (QD) has any shape that satisfies this optical property; the shape is not limited to a spherical tridimensional shape (circular cross-section shape). For instance, each quantum dot may have a polygonal cross-section shape, a bar-shaped tridimensional shape, a branch-shaped tridimensional shape, a tridimensional shape having surface asperities, or a combination of them.

The emission layer 11EM can be formed by subjecting each subpixel to separate coloring through, for instance, spin coating or ink-jet printing using a dispersion solution with quantum dots dispersed in a solvent, such as hexane, toluene, octadecane, cyclododecene, or phenylcyclohexane. Each quantum dot may be provided a ligand on its surface. The dispersion solution containing quantum dots may contain a dispersing material, such as thiol or amine. Further, the emission layer 11EM including quantum dots may be deposited onto the hole transport layer 11HT through electrophoretic deposition using the surface potential of the quantum dots.

### Electron Transport Layer

FIG. 2 illustrates the schematic of MgZnO@ZnO-NPs contained in the electron transport layer 11ET provided in the light-emitting element 1 according to the embodiment of the present disclosure. The MgZnO@ZnO-NPs illustrated in FIG. 2 are composed of zinc oxide carrier particles (ZnO-NPs) supporting zinc oxide nanoparticles doped with a magnesium (Mg) dopant (MgZnO-NPs). When, as illustrated in FIG. 2, the zinc oxide nanoparticles doped with a magnesium (Mg) dopant are composite zinc oxide nanoparticles supported on the surface of a zinc oxide carrier nanoparticle, the composite zinc oxide nanoparticles are also referred to as MgZnO-carrier ZnO nanoparticles or MgZnO@ZnO-NPs in some cases. It is intended in the MgZnO@ZnO-NPs that the ZnO-NPs are carrier particles, and that the MgZnO-NPs are particles supported by the carrier particles.

As illustrated in FIG. 2, the MgZnO@ZnO-NPs are presumed to have a structure in which the MgZnO-NPs supported by the ZnO-NPs form surface asperities on the ZnO-NPs, and in which the surfaces of the ZnO-NPs are exposed. In this regard, the structure of the MgZnO@ZnO-NPs is presumed to be different from a core-shell structure, a core-shell-shell structure, and a core-shell structure with the shell ratio continuously changed, all of which can be the structure of the foregoing quantum dots (QD). Further, the composite zinc oxide nanoparticles illustrated as the MgZnO@ZnO-NPs in FIG. 2 may be provided with a ligand coordinating on their surfaces. When the ZnO-NPs/ligand illustrated in FIG. 2 are provided with an organic ligand, this ligand can be intended that a part of the ligand serving as a dispersing material coordinates on the surfaces of the ZnO-NPs. Further, when the ZnO-NPs/ligand illustrated in FIG. 2 are provided with an inorganic ligand, it can be intended that the ZnO-NPs/ligand are ZnO-NPs each having a core-shell structure composed of an inorganic ligand. The ZnO-NPs/ligand may be provided with an inorganic ligand and further provided with an organic ligand.

A dispersion solution containing such MgZnO@ZnO-NPs (MgZnO@ZnO-NPs-dispersed solution) may contain ligands as a dispersing material; an example of the dispersing material is organic ligands not coordinating with the MgZnO@ZnO-NPs. An example of such ligands not coordinating with the MgZnO@ZnO-NPs is ligands similar to ligands that are used for ZnO carrier particles and doped ZnO nanoparticles, both of which will be described later on.

The electron transport layer 11ET transports electrons from the second electrode 12 or cathode to the emission layer 11EM by the use of an electron transport material. The doped zinc oxide nanoparticles are supported on the surface of the zinc oxide carrier particle (ZnO carrier particle), so that the composite zinc oxide nanoparticles (composite ZnO nanoparticles) have a higher energy level of the conduction band minimum (CBM) corresponding to the lowest unoccupied molecular orbital than zinc oxide nanoparticles (ZnO nanoparticles) containing no dopant. As such, the electron transport layer 11ET can achieve carrier balance with the hole injection layer 11HI without impairing the hole injection capability of the nickel oxide nanoparticles contained in the hole injection layer 11HI.

The dopant doped in the ZnO nanoparticles is not limited to magnesium (Mg) as long as the dopant can increase the energy level of the CBM of ZnO. An example of such a dopant is a metal atom, including aluminum (Al) and lithium (Li). ZnO containing a magnesium (Mg) dopant, ZnO containing an aluminum (Al) dopant, and ZnO containing a lithium (Li) dopant may be referred to as, but not limited to, MgZnO, AlZnO, and LiZnO, respectively. Further, ZnO nanoparticles doped with a dopant may be simply referred to as “doped ZnO nanoparticles”.

In the electron transport material, the mass ratio between the ZnO carrier particles and doped ZnO nanoparticles preferably ranges from 1:2 to 5:1 and more desirably ranges from 3:1 to 5:1. At a 1:2 to 5:1 mass ratio of the ZnO carrier particles to the doped ZnO nanoparticles, the larger the mass ratio of the ZnO carrier particles is, the better the carrier balance can be achieved, thereby improving the current response to a voltage in a light-emitting element, thereby enhancing the external quantum efficiency (EQE) of the light-emitting element.

The median diameter (D50) of the ZnO carrier particles is preferably larger than the D50 of the doped ZnO nanoparticles and is preferably 6 to 10 times as large as the D50 of the doped ZnO nanoparticles. This enables the doped ZnO nanoparticles to be successfully supported on the surfaces of the ZnO carrier particles by van der Waals forces. The ZnO carrier particles, although being referred to as ZnO carrier particles in the Description in order to distinguish them from the doped ZnO nanoparticles, can be ZnO nanoparticles not substantially doped with a dopant.

The D50 of the ZnO carrier particles is determined as a cumulative distribution on a volumetric basis. This D50 needs to range from 10 to 60 nm and preferably ranges from 10 to 20 nm. The smaller the D50 of the ZnO carrier particles is, the more suitably light from the emission layer 11EM can be transmitted through the second electrode 12 or cathode. As such, the first electrode 10 or anode made of an electrode material that reflects visible light, and the second electrode 12 or cathode made of an electrode material that transmits visible light can be suitably used as constituting a top-emission light-emitting element. It is noted that as earlier described, the first electrode 10 made of an electrode material that transmits visible light, and the second electrode 12 made of an electrode material that reflects visible light can be used as constituting a bottom-emission light-emitting element. The D50s of nanoparticles including the D50 of the ZnO carrier particles and the D50 of the doped ZnO nanoparticles (described later on) can be evaluated through a dynamic light scattering method.

The ZnO carrier particles can be each provided with a ligand. The ligands coordinating with the ZnO carrier particles are organic ligands, which are organic compounds each having a functional group and a hydrocarbon group. The ligand can have a function in which the functional group coordinates with the ZnO carrier particle, and the hydrocarbon group enhances the stability of dispersion of the ZnO carrier particle into, but not limited to, a polar solvent and an alcohol-based solvent, both of which will be described later on. An example of the functional group of the ligand is a functional group capable of coordinating on the surface of the ZnO carrier particle, such as an amino group, a thiol group, a carboxyl group, a hydroxyl group, and a phosphonyl group. The ligand may have a plurality of functional groups, such as diamine and dithiol, or may have a plurality of types of functional groups, such as carbamate and thiol-carboxylic acid. The hydrocarbon group of the ligand may be a liner-chained or branched hydrocarbon group. Alternatively, the hydrocarbon group may be an unsaturated hydrocarbon group, a saturated hydrocarbon group, or an aromatic hydrocarbon group. The ligand can be a ligand that is publicly known as a capping ligand. A plurality of types of ligands may be coordinated with the ZnO carrier particle. Examples of the ligands include oleylamine, octanethiol, tributylphosphine oxide. Another example of the ligands is an anion moiety constituting a quaternary ammonium salt, such as tetrabutylammonium tetrafluoroborate This anion moiety, which is a ligand, may be coordinated with the ZnO carrier particle. Other than the foregoing, the ligand of the ZnO carrier particle needs to be a metal chalcogenide compound other than ZnO; the ligand may be, for example, an inorganic ligand, such as zinc sulfide (ZnS).

The D50 of the doped ZnO nanoparticles is determined as a cumulative distribution on a volumetric basis. This D50 needs to range from 5 to 15 nm and preferably ranges from 5 to 10 nm.

The doped ZnO nanoparticles can be each provided with a ligand. The ligands coordinating with the doped ZnO nanoparticles can be selected in accordance with the type of the doped ZnO nanoparticles. Other than the foregoing, the ligands coordinating with the doped ZnO nanoparticles can be similar to the ligands of the ZnO carrier particles; thus, the description of these ligands will be omitted.

The composite ZnO nanoparticles, including MgZnO-carrier ZnO nanoparticles, are obtained by mixing a dispersion solution containing ZnO carrier particles and a dispersion solution containing doped ZnO nanoparticles together to prepare a mixed dispersion solution, followed by drying the mixed dispersion solution to cause the ZnO carrier particles to support MgZnO nanoparticles.

The dispersion solution containing ZnO carrier particles contains ZnO carrier particles and an organic solvent and can further contain ligands coordinating with the ZnO carrier particles. An example of the organic solvent contained in the dispersion solution is an alcohol-based solvent, such as ethanol. The dispersion solution containing ZnO carrier particles can contain a publicly known dispersing material as ligands.

The dispersion solution containing doped ZnO nanoparticles contain doped ZnO nanoparticles and an organic solvent and can further contain ligands coordinating with the doped ZnO nanoparticles. An example of the organic solvent contained in the dispersion solution is an alcohol-based solvent, such as ethanol. The dispersion solution containing doped ZnO nanoparticles can contain a publicly known dispersing material as ligands, like the dispersion solution containing ZnO carrier particles.

In each of the dispersion solution containing ZnO carrier particles and the dispersion solution containing doped ZnO nanoparticles, the type of the ligands coordinating with the ZnO carrier particles and the type of the ligands coordinating with the doped ZnO nanoparticles may be different from or identical to each other. Here, it is preferable that the organic solvent within the dispersion solution containing ZnO carrier particles and the organic solvent within the dispersion solution containing doped ZnO nanoparticles be miscible or identical to each other. This dissolution and mixture of the organic solvent within the dispersion solution containing doped ZnO nanoparticles and the organic solvent within the dispersion solution containing ZnO carrier particles can enhance the dispersion stability of the ZnO carrier particles coordinated with ligands and of the doped ZnO nanoparticles coordinated with ligands. This can avoid the mixed dispersion solution from unintentionally turning into a milky solution, which is produced when the ZnO carrier particles support the doped ZnO nanoparticles.

The concentration of the composite ZnO nanoparticles contained in the mixed dispersion solution needs to be appropriately regulated such that an electron transport layer having a desired thickness can be formed.

Drying the mixed dispersion solution with these dispersion solutions mixed together enables the ZnO carrier particles to support the doped ZnO nanoparticles while slipping through the ligands of the ZnO carrier particles. This can obtain composite ZnO particles. The obtained composite ZnO nanoparticles need to be dispersed into an organic solvent, such as hexanol or octanol, to a desired concentration, thereby obtaining a dispersion solution containing composite ZnO nanoparticles. The composite ZnO nanoparticles are turned into reverse micelles within the organic solvent by the ligands coordinating with the ZnO carrier particles and/or the ligands coordinating with the doped ZnO nanoparticles, so that the composite ZnO nanoparticles can be stabilized. Thereafter, the dispersion solution containing composite ZnO nanoparticles is applied through, for instance, spinner coating or ink-jet coating, thereby achieving the electron transport layer 11ET having high flatness. It is noted that the application of the dispersion solution containing composite ZnO nanoparticles needs to be followed by drying through heating at a temperature of 25 to 110° C. for instance, preferably at a temperature of 25 to 80° C. It is also noted that the electron transport layer 11ET after dried through heating may undergo cleaning or rinse with an organic solvent.

It is also noted that the electron transport layer 11ET containing composite ZnO nanoparticles may be formed by depositing composite ZnO nanoparticles onto the emission layer 11EM through electrophoretic deposition.

The electron transport layer 11ET formed in the foregoing manner needs to have a thickness ranging 20 to 200 nm and preferably has a thickness ranging from 50 to 150 nm. This enables a cavity effect to be exerted, thereby enhancing the directivity of light emitted from the emission layer 11EM through the electron transport layer 11ET. In addition, from another point of view, the electron transport layer 11ET having a thickness of 50 nm or greater can alleviate damage to the emission layer 11EM when the second electrode 12 is formed through, but not limited to, an ITO sputtering process.

In a known method, the electron transport layer of a light-emitting element is composed of two layers in some cases: one is a layer containing metal oxide, such as zinc oxide (ZnO); and the other is a layer containing metal oxide, such as zinc oxide (MₓZn_{y}O) doped with metal atoms. As described above, if such two electron transport layers are formed, an emission layer that has been formed and contains quantum dots is exposed to the solvent of a dispersion solution for forming an electron transport layer and heated at least twice. This lowers the flatness of the two electron transport layers, thereby causing an imbalance in electron transfer in the electron transport layers, thereby increasing the possibility of non-uniform light emission. In addition, the metal oxide of the nanoparticles within the electron transport layers is distributed unevenly, thus possibly causing thermal damage to the emission layer, which is below the electron transport layers.

In this regard, the light-emitting element 1 according to one embodiment is advantageous, because it is formed such that not only the electron transport layer 11ET, which has a high CBM, achieves carrier balance with the hole injection layer 11HI, but also the emission layer 11EM and electron transport layer 11ET themselves do not lose their uniformity by applying composite ZnO nanoparticles, which are the electron transport material of the electron transport layer 11ET, at one time.

In addition, the electron transport layer 11ET can achieve the carrier balance without impairing the high hole injection capability of the hole injection layer 11HI including nickel oxide nanoparticles. Consequently, the light-emitting element 1 can improve the current response to a voltage and can enhance external quantum efficiency.

The emission layer 11EM in the light-emitting element 1 according to one embodiment can emit any one of red light, green light, and blue light. Here, the red light is light having an emission center wavelength in a wavelength band ranging from 600 nm exclusive to 780 nm inclusive. Further, the green light is light having an emission center wavelength in a wavelength band ranging from 500 nm exclusive to 600 nm inclusive. Furthermore, the blue light is light having an emission center wavelength in a wavelength band ranging from 400 to 500 nm inclusive. It is noted that although a plurality of types of quantum dots are a combination of red, green, and blue quantum dots in one embodiment, they do not necessarily have to be this combination.

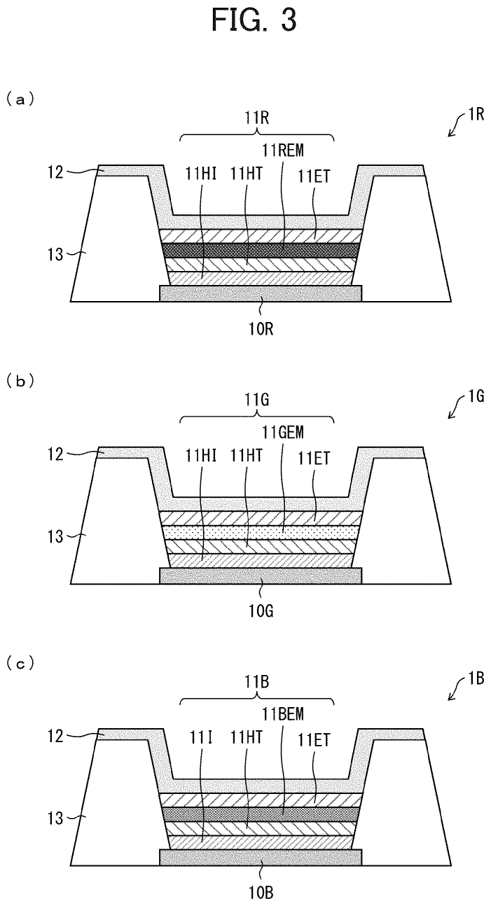

FIG. 3(a) illustrates a red light-emitting element 1R provided with a functional layer 11R including a red emission layer 11REM that emits red light. FIG. 3(b) illustrates a green light-emitting element 1G provided with a functional layer 11G including a green emission layer 11GEM that emits green light. FIG. 3(c) illustrates a blue light-emitting element 1B provided with a functional layer 11B including a blue emission layer 11BEM that emits blue light.

This embodiment describes, by way of example, an instance where the red light-emitting element 1R, the green light-emitting element 1G, and the blue light-emitting element 1B are quantum-dot light-emitting diodes (QLEDs). One or some of the red light-emitting element 1R, green light-emitting element 1G, and blue light-emitting element 1B may be a QLED(s), and the other(s) may be an OLED(s). Furthermore, the red light-emitting element 1R, the green light-emitting element 1G, and the blue light-emitting element 1B may be organic light-emitting diodes (OLEDs). It is noted that where the red light-emitting element 1R, the green light-emitting element 1G, and the blue light-emitting element 1B are QLEDs, the emission layers provided in the respective colored light-emitting elements are emission layers including quantum dots formed through, for instance, application or ink-jet printing, and that where the red light-emitting element 1R, the green light-emitting element 1G, and the blue light-emitting element 1B are OLEDs, the emission layers provided in the respective colored light-emitting elements are organic emission layers formed through, for instance, evaporation.

The red light-emitting element 1R includes a first electrode 10R, the functional layer 11R including the red emission layer 11REM, and the second electrode 12. The green light-emitting element 1G includes a first electrode 10G, the functional layer 11G including the green emission layer 11GEM, and the second electrode 12. The blue light-emitting element 1B includes a first electrode 10B, the functional layer 11B including the blue emission layer 11BEM, and the second electrode 12. It is noted that an insulating bank 13 (resin layer) covering the individual edges of the first electrodes 10R, 10G, and 10B can be formed by applying an organic material, such as polyimide or acrylic, followed by patterning it onto a flattening film, which will be described later on, through photolithography.

Further, the functional layers 11R, 11G, and 11B illustrated in FIGS. 3(a) to (c) may be provided with hole injection layers formed in the same process step using the same material, hole transport layers formed in the same process step using the same material, and electron transport layers formed in the same process step using the same material.

### Display Device

A display device according to one embodiment of the present disclosure is provided with a plurality of light-emitting elements each provided with a functional layer including the following in the stated order between a first electrode and a second electrode: a hole transport layer containing nickel oxide nanoparticles, an emission layer, and an electron transport layer containing composite ZnO nanoparticles. These light-emitting elements are provided on a substrate. Although the following describes a plurality of light-emitting elements that emit light having different emission peak wavelengths, the plurality of light-emitting elements may emit light of the same color. Further, in one embodiment, the functional layer provided in a light-emitting element of a display device needs to contain nickel oxide nanoparticles in the hole transport layer or the hole injection layer; although this embodiment describes an instance where the hole injection layer contains nickel oxide nanoparticles, the hole injection layer is not an essential constituent.

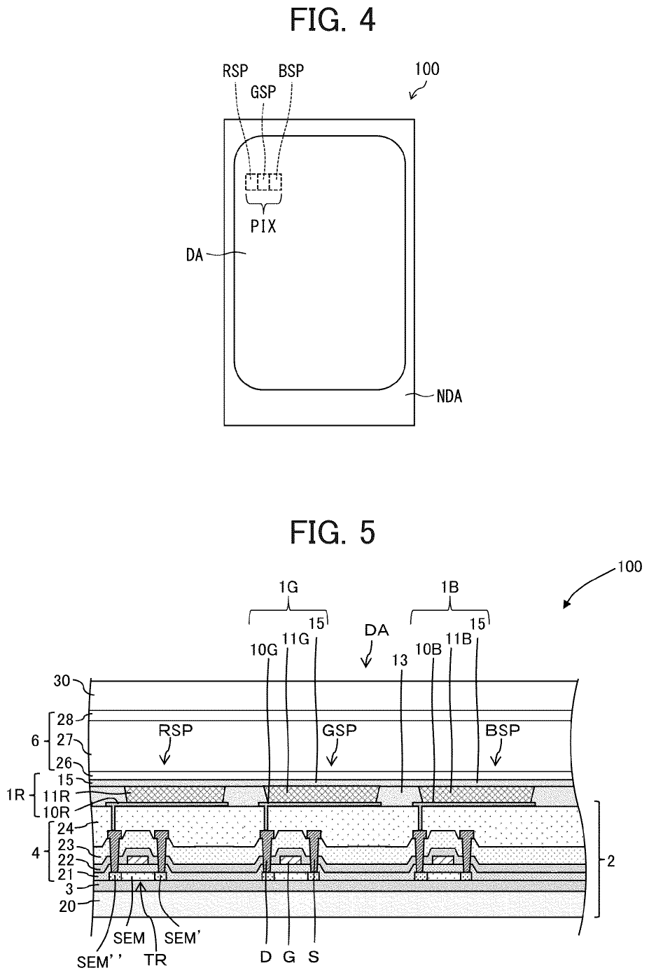

FIG. 4 is a plan view of the schematic configuration of a display device 100 according to the first embodiment. FIG. 5 is a cross-sectional view of the schematic configuration of a display region DA of the display device 100 according to the embodiment of the present disclosure.

As illustrated in FIG. 4, the display device 100 has a frame region NDA and the display region DA. The display region DA of the display device 100 has a plurality of pixels PIX. Each pixel PIX includes a red subpixel RSP, a green subpixel GSP, and a blue subpixel BSP. This embodiment of the present disclosure describes, by way of example, an instance where a single pixel PIX is composed of the red subpixel RSP, green subpixel GSP, and blue subpixel BSP. For instance, a single pixel PIX may further include a subpixel of another color other than the red subpixel RSP, green subpixel GSP, and blue subpixel BSP.

The red subpixel RSP, green subpixel GSP, and blue subpixel BSP illustrated in FIG. 4 include the red light-emitting element 1R, green light-emitting element 1G, and blue light-emitting element 1B illustrated in FIGS. 3(a) to (c), respectively. To be more specific, the red subpixel RSP illustrated in FIG. 5 includes the red light-emitting element IR, the green subpixel GSP illustrated in FIG. 5 includes the green light-emitting element 1G, and the blue subpixel BSP illustrated in FIG. 5 includes the blue light-emitting element 1B. It is noted that a control circuit including transistors TR, which are provided for each of the red subpixel RSP, green subpixel GSP, and blue subpixel BSP, and a corresponding one of the light-emitting elements are collectively referred to as a subpixel circuit.

As illustrated in FIG. 5, in the display region DA of the display device 100 is the following components provided on a substrate 20 in the stated order from the substrate 20: a barrier layer 3; a thin-film transistor layer 4 including the transistors TR; the red light-emitting elements 1R, the green light-emitting elements 1G, the blue light-emitting elements 1B, and the bank 13 (transparent resin layer); a sealing layer 6; and a functional film 30. It is noted that such a substrate as illustrated in FIG. 5, i.e., the substrate 20 on which the barrier layer 3, the thin-film transistor layer 4 including the transistors TR, and the plurality of first electrodes 10R, 10G, and 10B are provided in the stated order from the substrate 20, will be referred to as a substrate (active matrix substrate) 2 provided with first electrodes.

The red subpixel RSP provided in the display region DA of the display device 100 includes the red light-emitting element 1R (first light-emitting element). The green subpixel GSP provided in the display region DA of the display device 100 includes the green light-emitting element 1G (second light-emitting element). The blue subpixel BSP provided in the display region DA of the display device 100 includes the blue light-emitting element 1B (third light-emitting element). The red light-emitting element 1R included in the red subpixel RSP includes the first electrode 10R; the functional layer 11R including a red emission layer, and the second electrode 12. The green light-emitting element 1G included in the green subpixel GSP includes the first electrode 10G, the functional layer 11G including a green emission layer, and the second electrode 12. The blue light-emitting element 1B included in the blue subpixel BSP includes the first electrode 10B, the functional layer 11B including a blue emission layer, and the second electrode 12.

The substrate 20 may be, for instance, a resin substrate made of resin, such as polyimide, or a glass substrate. This embodiment describes, by way of example, an instance where a resin substrate made of resin, such as polyimide, is used as the substrate 20 so that the display device 100 is a flexible display device. For the display device 100 to be a non-flexible display device, a glass substrate can be used as the substrate 20.

The barrier layer 3 is a layer that prevents foreign substances, such as water and oxygen, from entering the transistors TR, red light-emitting element 1R, green light-emitting element 1G, and blue light-emitting element 1B. The barrier layer 3 can be composed of a silicon oxide film, a silicon nitride film, or a silicon oxide nitride film, all of which are formed through chemical vapor deposition (CVD) for instance, or a laminate of these films.

A transistor-TR portion of the thin-film transistor layer 4 including the transistors TR includes the following: a semiconductor film SEM, and doped semiconductor films SEM′ and SEM″; an inorganic insulating film 21; a gate electrode G; an inorganic insulating film 22; an inorganic insulating film 23; a source electrode S and a drain electrode D; and a flattening film 24. A portion excluding the transistor-TR portion of the thin-film transistor layer 4 including the transistors TR includes the inorganic insulating film 21, the inorganic insulating film 22, the inorganic insulating film 23, and the flattening film 24.

The semiconductor films SEM, SEM′, and SEM″ may be composed of, for instance, low-temperature polysilicon (LTPS) or an oxide semiconductor (e.g., an In—Ga—Zn—O semiconductor). Although this embodiment describes, by way of example, an instance where the transistors TR have a top-gate structure, the transistors TR may have a bottom-gate structure.

The gate electrode G, the source electrode S, and the drain electrode D can be composed of, for instance, a metal monolayer film or metal multilayer film containing at least one of aluminum, tungsten, molybdenum, tantalum, chromium, titanium, and copper.

The inorganic insulating film 21, the inorganic insulating film 22, and the inorganic insulating film 23 can be composed of a silicon oxide film, a silicon nitride film, or a silicon oxide nitride film, all of which are formed through CVD for instance, or a laminate of these films.

The flattening film 24 can be composed of an organic material that can be applied, such as polyimide or acrylic.

The red light-emitting element 1R includes the first electrode 10R positioned above the flattening film 24, the functional layer 11R including the red emission layer, and the second electrode 12. The green light-emitting element 1G includes the first electrode 10G positioned above the flattening film 24, the functional layer 11G including the green emission layer, and the second electrode 12. The blue light-emitting element 1B includes the first electrode 10B positioned above the flattening film 24, the functional layer 11B including the blue emission layer, and the second electrode 12. It is noted that the bank 13 (transparent resin layer), which is insulating and covers the individual edges of the first electrodes 10R, 10G, and 10B, can be formed by applying an organic material, such as polyimide or acrylic, followed by patterning it through photolithography.

The sealing layer 6 is a light-transparent film and can be composed of, for example, an inorganic sealing film 26 covering the second electrode 12, an organic film 27 positioned above the inorganic sealing film 26, and an inorganic sealing film 28 positioned above the organic film 27. The sealing layer 6 prevents foreign substances, such as water and oxygen, from permeating the red light-emitting element 1R, the green light-emitting element 1G, and the blue light-emitting element 1B.

The inorganic sealing film 26 and the inorganic sealing film 28 are each an inorganic film and can be composed of a silicon oxide film, a silicon nitride film, or a silicon oxide nitride film, all of which are formed through CVD for instance, or a laminate of these films. The organic film 27 is an organic light-transparent film with a flattening effect and can be composed an organic material that can be applied, such as acrylic. The organic film 27 may be formed through ink-jet printing for instance. Although this embodiment has described, by way of example, an instance where the sealing layer 6 is composed of two inorganic films and one organic film provided between the two inorganic films, the order of stacking two inorganic films and one organic film is not limited to this instance. Furthermore, the sealing layer 6 may be composed of only an inorganic film or only an organic film; alternatively, the layer may be composed of one inorganic film and two organic films; alternatively, the layer may be composed of two or more inorganic films and two or more organic films.

The functional film 30 is a film having at least one of, for instance, an optical-compensation function and a protection function.

As described above, a light-emitting element according to a first aspect of the present disclosure includes a first electrode, a second electrode, and a functional layer provided between the first electrode and the second electrode. The functional layer includes the foregoing hole transport layer, emission layer, and electron transport layer. The hole transport layer contains a nickel oxide nanoparticle. The electron transport layer contains a composite zinc oxide nanoparticle. The composite zinc oxide nanoparticle includes a zinc oxide carrier particle supporting a zinc oxide nanoparticle doped with a dopant.

Consequently, the light-emitting element can achieve the carrier balance of the electron transport layer without impairing the high hole injection capability of nickel oxide nanoparticles by using nickel oxide nanoparticles for the hole transport layer.

The light-emitting element according to a second aspect of the present disclosure is preferably configured in the first aspect such that the dopant is a metal atom selected from the group consisting of Mg, Li, and Al.

This can raise the CBM energy level of the electron transport layer, thereby achieving the carrier balance between the hole transport layer and electron transport layer without impairing the high hole injection capability of the nickel oxide nanoparticles.

The light-emitting element according to a third aspect of the present disclosure needs to be configured in the first or second aspect such that the mass ratio between the zinc oxide carrier particle contained in the electron transport layer and the zinc oxide nanoparticle doped with the dopant ranges from 2:1 to 1:5.

This can obtain the light-emitting element with high external quantum efficiency.

The light-emitting element according to a fourth aspect of the present disclosure is preferably configured in any one of the first to third aspects such that the median diameter (D50) of the zinc oxide carrier particle is larger than the median diameter (D50) of the zinc oxide nanoparticle doped with the dopant.

This enables the zinc oxide carrier particle to successfully support the zinc oxide nanoparticle doped with the dopant.

The light-emitting element according to a fifth aspect of the present disclosure is preferably configured in any one of the first to fourth aspects such that the median diameter (D50) of the zinc oxide carrier particle ranges from 10 to 60 nm.

This also enables the zinc oxide carrier particle to successfully support the zinc oxide nanoparticle doped with the dopant, thereby allowing light generated in the emission layer to successfully pass from a reflective anode through a transparent cathode.

The light-emitting element according to a sixth aspect of the present disclosure needs to be configured in any one of the first to fifth aspects such that the median diameter (D50) of the zinc oxide nanoparticle doped with the dopant ranges from 5 to 15 nm.

This also enables the zinc oxide carrier particle to successfully support the zinc oxide nanoparticle containing a metal atom as a dopant.

A display device according to a seventh aspect of the present disclosure is provided with the following: a substrate; and a plurality of the light-emitting elements according to any one of the first to sixth aspects on the substrate.

The display device according to an eighth aspect of the present disclosure needs to be configured in the seventh aspect such that the plurality of light-emitting elements are light-emitting elements configured to emit light of an identical color.

The display device according to an eighth aspect of the present disclosure needs to be configured in the seventh aspect such that the plurality of light-emitting elements include a first light-emitting element, a second light-emitting element, and a third light-emitting element, such that the first light-emitting element is provided with a first emission layer as the emission layer, such that the second light-emitting element is provided with, as the emission layer, a second emission layer whose emission peak wavelength is different from the emission peak wavelength of the first emission layer, and such that the third light-emitting element is provided with, as the emission layer, a third emission layer whose emission peak wavelength is different from the emission peak wavelengths of the first emission layer and the second emission layer.

The display device according to the sixth to eighth aspects can be a display device provided with a light-emitting element with high external quantum efficiency.

The present disclosure is not limited to the foregoing embodiments. Various modifications can be made within the scope of the claims. An embodiment that is obtained in combination as appropriate with the technical means disclosed in the respective embodiments is also encompassed within the technical scope of the present disclosure.

### EXAMPLES

Examples of the present disclosure will be described below.

Light-emitting elements in Examples 1 and 2 and Comparative Examples 1 and 2 whose ETLs were different from each other were produced and their optical-electrical properties were evaluated.

### Preparation of Composition for ETL Formation

Compositions in Examples 1 and 2 whose ZnO: MgZnO mass ratios were different from each other, and compositions in Comparative Examples 1 and 2 were prepared, as listed below.
Example 1: MgZnO@ZnO-NPs (ZnO:MgZnO mass ratio is 3:1)
Example 2: MgZnO@ZnO-NPs (ZnO:MgZnO mass ratio is 5:1)
Comparative Example 1: ZnO-NPs
Comparative Example 2: MgZnO-NPs

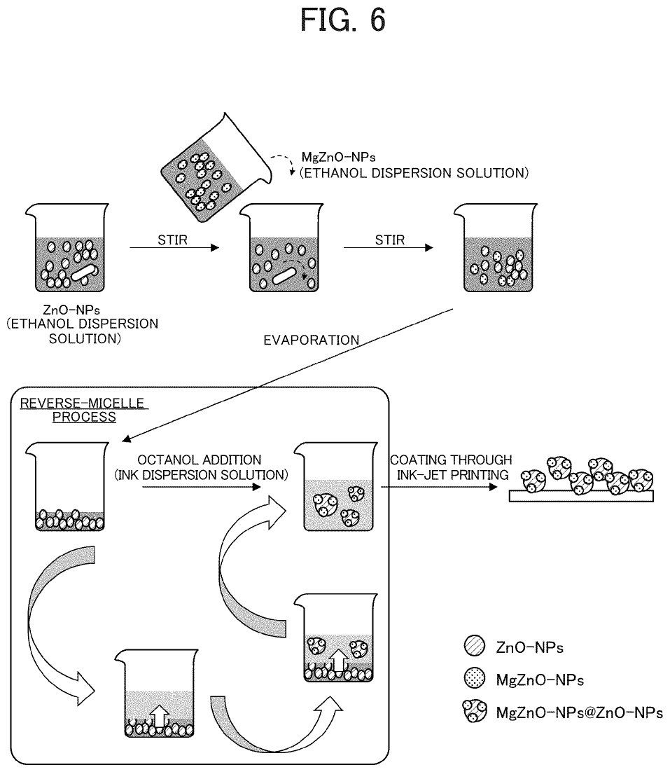

With regard to Example 1, a dispersion solution containing MgZnO@ZnO-NPs was prepared in line with the scheme shown in FIG. 6. First, an ethanol dispersion solution containing MgZnO-NPs (a concentration of 20 mg/mL; D50 of MgZnO=5 nm) was added to an ethanol dispersion solution containing ZnO-NPs (a concentration of 5 wt %; D50 of ZnO=11 nm) with the ZnO-NPs ethanol dispersion solution being stirred with a magnetic stirrer, such that ZnO:MgZnO was a predetermined mass ratio. Accordingly, a mixed dispersion solution with ZnO and MgZnO uniformly dispersed was obtained. Thereafter, the ethanol contained in the mixed dispersion solution was removed using an evaporator, thus obtaining a solid. Octanol was added to the obtained solid, and the resulting mixture was stirred to obtain a re-dispersion solution in which ZnO supporting MgZnO within the octanol was turned into reverse micelles. The obtained re-dispersion solution underwent centrifugal separation at 4000 rpm for 3 minutes or longer to confirm that there was no precipitate in the re-dispersion solution, thereby obtaining a stable dispersion solution containing nanoparticles. The re-dispersion solution underwent filtering with a syringe filter of 0.22 μm in pore diameter to obtain the composition in Example 1 containing MgZnO@ZnO-NPs.

Next, the composition in Example 2 was obtained in line with the same procedure as that in Example 1 with the exception that the ZnO:MgZnO mass ratio was changed from 3:1 to 5:1. Subsequently, the composition in Comparative Example 1 was obtained in line with the same procedure as that in Example 1 with the exception that only an ethanol dispersion solution containing ZnO-NPs was used. Similarly, the composition in Comparative Example 2 was obtained in line with the same procedure as that in Example 1 with the exception that only an ethanol dispersion solution containing MgZnO-NPs was used.

### Production of Light-Emitting Element

A light-emitting element provided with a cathode, an electron transport layer (ETL), an emission layer (EML), a hole transport layer (HTL), a hole injection layer (HIL), and an anode was formed using each of the compositions in Examples 1 and 2 and Comparative Examples 1 and 2.

A material for forming each layer is as follows.
Cathode: ITO
ETL: Examples 1 and 2 and Comparative Examples 1 and 2 (90 nm in film thickness)
EML: QD
HTL: poly[(9,9-dioctylfluorenyl-2,7-dyl)-co-(4,4′-(N-(4-sec-butylphenyl))diphenylamine)](TFB)
HIL: NiO-NPs (75 nm in film thickness)
Anode: ITO-Ag-ITO

The composition in Example 1 was spin-coated onto the EML of a substrate on which an anode, an HIL, an HTL, and an EML were formed in the stated order from the backplane and was heated at 80° C. for 15 minutes to form an ETL. Thereafter, a cathode was formed onto the ETL through sputtering, thereby producing the light-emitting element in Example 1. In line with the same procedure as that in Example 1, the light-emitting elements in Example 2 and Comparative Examples 1 and 2 were produced.

Each of the light-emitting elements in Examples 1 and 2 and Comparative Examples 1 and 2 underwent an evaluation on the optical-electrical property (current density-EQE or external quantum efficiency).

Table 1 shows the evaluation results of the optical-electrical property (current density-EQE or external quantum efficiency). Table 1 reveals that at an equal current density, a light-emitting element provided with an ETL containing ZnO nanoparticles (MgZnO@ZnO-NPs) supporting MgZnO, like the light-emitting elements in Examples 1 and 2, has higher external quantum efficiency than a light-emitting element provided with an ETL containing ZnO-NPs of a single composition, like that in Comparative Example 1, or containing MgZnO-NPs, like that in Comparative Example 2.

TABLE 1

| | | | | | | | Comparative | | | Comparative | | |
|---|---|---|---|---|---|---|---|---|---|---|---|---|
| | Example 1 | | | Example 2 | | | Example 1 | | | Example 2 | | |
| | EML | | | | | | | | | | | |
| | MgZnO@ZnO | | | MgZnO@ZnO | | | | | | | | |
| | (3:1) | | | (5:1) | | | ZnO | | | MgZnO | | |
| Current Density | 10 | 20 | 30 | 10 | 20 | 30 | 10 | 20 | 30 | 10 | 20 | 30 |
| (mA · cm⁻²) | | | | | | | | | | | | |
| External | 14 | 12 | 12 | 12 | 11 | 11 | 8 | 8 | 7.0 | 6 | 5.0 | 5.0 |
| Quantum | | | | | | | | | | | | |
| Efficiency (%) | | | | | | | | | | | | |

### REFERENCE SIGNS LIST

1 light-emitting element
1R red light-emitting element (light-emitting element)
1G green light-emitting element (light-emitting element)
1B blue light-emitting element (light-emitting element)
10, 10R, 10G, 10B first electrode (anode)
11 functional film
11HI hole injection layer (hole transport layer)
11HT hole transport layer
11EM emission layer
11REM red emission layer
11GEM green emission layer
11BEM blue emission layer
11ET electron transport layer
12 second electrode (cathode)
13 bank (transparent resin layer)
100 display device
3 barrier layer
4 thin-film transistor layer
6 sealing layer
20 substrate
21, 22, 23 inorganic insulating film
24 flattening film
26, 28, inorganic sealing film
27 organic film
30 functional film
PIX pixel
RSP red subpixel
GSP green subpixel
BSP blue subpixel
TR transistor
G gate electrode
D drain electrode
S source electrode
DA display region
NDA frame region

1. A light-emitting element comprising:
a first electrode;
a second electrode; and
a functional layer provided between the first electrode and the second electrode,
wherein the functional layer includes a hole transport layer, an emission layer, and an electron transport layer,
the hole transport layer contains a nickel oxide nanoparticle,
the electron transport layer contains a composite zinc oxide nanoparticle, and
the composite zinc oxide nanoparticle includes a zinc oxide carrier particle supporting a zinc oxide nanoparticle doped with a metal atom as a dopant.

2. The light-emitting element according to claim 1, wherein the metal atom is selected from the group consisting of Mg, Li, and Al.

3. The light-emitting element according to claim 1, wherein the composite zinc oxide nanoparticle includes the zinc oxide carrier particle and the zinc oxide nanoparticle doped with the dopant at a mass ratio ranging from 2:1 to 1:5.

4. The light-emitting element according to claim 1, wherein a median diameter (D50) of the zinc oxide carrier particle is larger than a median diameter (D50) of the zinc oxide nanoparticle doped with the dopant.

5. The light-emitting element according to claim 1, wherein a median diameter (D50) of the zinc oxide carrier particle ranges from 10 to 60 nm.

6. The light-emitting element according to claim 1, wherein a median diameter (D50) of the zinc oxide nanoparticle doped with the dopant ranges from 5 to 15 nm.

7. A display device comprising:
a substrate; and
a plurality of the light-emitting elements according to claim 1 on the substrate.

8. The display device according to claim 7, wherein the plurality of light-emitting elements are light-emitting elements configured to emit light of an identical color.

9. The display device according to claim 7, wherein
the plurality of light-emitting elements include a first light-emitting element, a second light-emitting element, and a third light-emitting element,
the first light-emitting element is provided with a first emission layer as the emission layer,
the second light-emitting element is provided with, as the emission layer, a second emission layer whose emission peak wavelength is different from an emission peak wavelength of the first emission layer, and
the third light-emitting element is provided with, as the emission layer, a third emission layer whose emission peak wavelength is different from the emission peak wavelengths of the first emission layer and the second emission layer.
